(19) United States
(12) Patent Application Publication
(10) Pub. No.: US 2023/0369067 A1
(43) Pub. Date: Nov. 16, 2023

(54) POWER ELECTRONIC SYSTEM AND METHOD FOR FABRICATING A POWER ELECTRONIC SYSTEM

(71) Applicant: Infineon Technologies AG, Neubiberg (DE)

(72) Inventor: Christoph Koch, Salzkotten (DE)

(21) Appl. No.: 18/141,102

(22) Filed: Apr. 28, 2023

(30) Foreign Application Priority Data
May 10, 2022 (DE) 102022111590.9

(51) Int. Cl. H01L 21/48; H01L 23/13; H01L 23/467; H01L 23/473

(52) U.S. Cl. CPC H01L 21/4882; H01L 23/13; H01L 23/467; H01L 23/473

(57) ABSTRACT

A power electronic system includes a power semiconductor module, including: a baseplate having a first side, an opposite second side, and an edge connecting the first and second sides; and a power semiconductor die arranged at the first side of the baseplate; and a cooler having an opening. The edge of the baseplate is in direct contact with an edge of the opening such that a fluid channel provided by the cooler is sealed at the opening by the baseplate and the second side of the baseplate forms a wall of the fluid channel. An interface between the baseplate and the cooler at the opening is free of any welded joint.

### TECHNICAL FIELD

This disclosure relates in general to a power electronic system as well as to a method for fabricating a power electronic system.

### BACKGROUND

A power electronic system comprises at least one power semiconductor module and a cooler configured to dissipate heat generated by the power semiconductor module during operation. A baseplate of the power semiconductor module(s) may be joined to the cooler such that the baseplate seals an opening in the cooler and such that a lower side of the baseplate can be in direct contact with a cooling fluid within the cooler. In order to seal the opening, in particular in a watertight manner, the baseplate may be required to have a comparatively large outer margin reserved for fastening structures, e.g. screw fixing areas, and/or a seal area. Furthermore, providing a tight seal may comprise one or more comparatively error-prone and/or time-consuming assembly processes which may for example increase the overall costs of the power electronic system. Improved power electronic systems as well as improved methods for fabricating power electronic systems may provide a solution for these and other problems.

The problem on which the invention is based is solved by the features of the independent claims. Further advantageous examples are described in the dependent claims.

### SUMMARY

Various aspects pertain to a power electronic system, comprising: a power semiconductor module, comprising: a baseplate comprising a first side, an opposite second side and an edge connecting the first and second sides and a power semiconductor die arranged at the first side of the baseplate; and a cooler comprising an opening, wherein the edge of the baseplate is in direct contact with an edge of the opening such that a fluid channel provided by the cooler is sealed at the opening by the baseplate and the second side of the baseplate forms a wall of the fluid channel, wherein an interface between the baseplate and the cooler at the opening is free of any welded joint.

Various aspects pertain to a power electronic system, comprising: a power semiconductor module, comprising: a baseplate comprising a first side, an opposite second side and an edge connecting the first and second sides and a power semiconductor die arranged at the first side of the baseplate; and a cooler comprising an opening, wherein the edge of the baseplate is in direct contact with an edge of the opening such that a fluid channel provided by the cooler is sealed at the opening by the baseplate and the second side of the baseplate forms a wall of the fluid channel, wherein the power semiconductor module and the cooler are joined in a reversible manner wherein heating the cooler and/or cooling down the baseplate to a relative temperature difference of 60° C. or more will release the joint.

Various aspects pertain to a power electronic system, comprising: a power semiconductor module, comprising: a baseplate comprising a first side, an opposite second side and an edge connecting the first and second sides and a power semiconductor die arranged at the first side of the baseplate; and a cooler comprising an opening, wherein the edge of the baseplate is in direct contact with an edge of the opening such that a fluid channel provided by the cooler is sealed at the opening by the baseplate and the second side of the baseplate forms a wall of the fluid channel, wherein a joint between the baseplate and the cooler is fabricated by a heat shrinking process or a thermal expansion process.

Various aspects pertain to a method for fabricating a power electronic system, the method comprising: providing a power semiconductor module, comprising: a baseplate comprising a first side, an opposite second side and an edge connecting the first and second sides and a power semiconductor die arranged at the first side of the baseplate, providing a cooler comprising an opening, and joining the power semiconductor module to the cooler using a heat shrinking process and/or a thermal expansion process such that the edge of the baseplate is in direct contact with an edge of the opening and such that a fluid channel provided by the cooler is sealed at the opening by the baseplate and the second side of the baseplate forms a wall of the fluid channel.

### BRIEF DESCRIPTION OF THE DRAWINGS

The accompanying drawings illustrate examples and together with the description serve to explain principles of the disclosure. Other examples and many of the intended advantages of the disclosure will be readily appreciated in view of the following detailed description. The elements of the drawings are not necessarily to scale relative to each other. Identical reference numerals designate corresponding similar parts.

FIGS. 1A and 1B each show a sectional view of a power electronic system before assembly (FIG. 1A) and after assembly (FIG. 1B).

FIGS. 2A and 2B each show a plan view of a cooler (FIG. 2A) and a power semiconductor module (FIG. 2B) which may be components of a power electronic system.

FIG. 3 shows a plan view of a lower side of a baseplate, wherein the baseplate is configured to be joined to a cooler.

FIG. 4 shows a sectional view of a detail of a power electronic system, wherein a polymer seal is arranged between a baseplate and a cooler.

FIG. 5 shows a sectional view of a detail of a power electronic system, wherein an edge of a baseplate comprises a ridge.

FIG. 6 shows a sectional view of a further power electronic system, wherein a power semiconductor substrate is arranged between a power semiconductor die and a baseplate.

FIG. 7 shows a plan view of a cooler for a power electronic system, wherein the cooler comprises a plurality of openings, each configured to accept a baseplate.

FIG. 8 is a flow chart of an exemplary method for fabricating a power electronic system.

### DETAILED DESCRIPTION

In the following detailed description, directional terminology, such as “top”, “bottom”, “left”, “right”, “upper”, “lower” etc., is used with reference to the orientation of the Figure(s) being described. Because components of the disclosure can be positioned in a number of different orientations, the directional terminology is used for purposes of illustration only. It is to be understood that other examples may be utilized and structural or logical changes may be made.

In addition, while a particular feature or aspect of an example may be disclosed with respect to only one of several implementations, such feature or aspect may be combined with one or more other features or aspects of the other implementations as may be desired and advantageous for any given or particular application, unless specifically noted otherwise or unless technically restricted. Furthermore, to the extent that the terms “include”, “have”, “with” or other variants thereof are used in either the detailed description or the claims, such terms are intended to be inclusive in a manner similar to the term “comprise”. The terms “coupled” and “connected”, along with derivatives thereof may be used. It should be understood that these terms may be used to indicate that two elements cooperate or interact with each other regardless whether they are in direct physical or electrical contact, or they are not in direct contact with each other; intervening elements or layers may be provided between the “bonded”, “attached”, or “connected” elements. However, it is also possible that the “bonded”, “attached”, or “connected” elements are in direct contact with each other. Also, the term “exemplary” is merely meant as an example, rather than the best or optimal.

An efficient power electronic system and an efficient method for fabricating a power electronic system may for example reduce material consumption, ohmic losses, chemical waste, etc. and may thus enable energy and/or resource savings. Improved power electronic systems and improved methods for fabricating a power electronic system, as specified in this description, may thus at least indirectly contribute to green technology solutions, i.e. climate-friendly solutions providing a mitigation of energy and/or resource use.

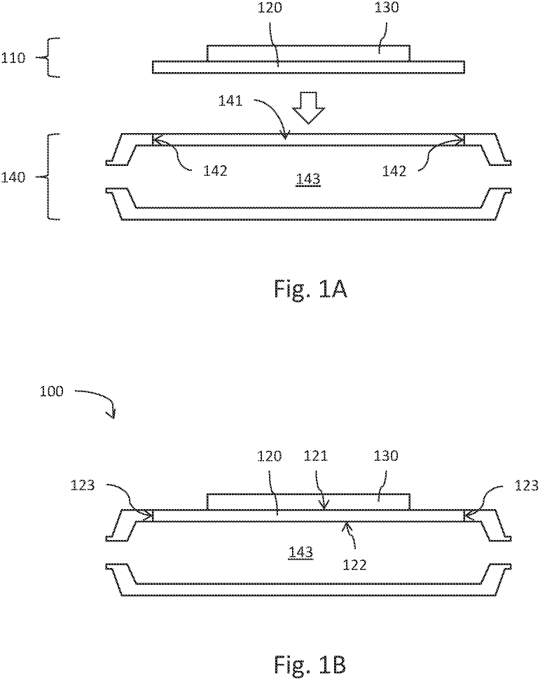

FIG. 1A shows a sectional view of a power semiconductor module 110 and a cooler 140 of a power electronic system 100 prior to assembly. FIG. 1B shows the power electronic system 100 after the power semiconductor module 110 and the cooler 140 have been joined together.

According to an example, the power electronic system 100 comprises a single power semiconductor module 110. According to another example, the power electronic system 100 comprises a plurality of power semiconductor modules 110. The power semiconductor modules 110 may be identical modules or different types of modules. Furthermore, the power semiconductor modules 110 may be electrically coupled to each other. It is however also possible that at least one of the power semiconductor modules 110 is not electrically coupled to other power semiconductor modules 110 of the power electronic system 100.

The power semiconductor module 110 comprises a baseplate 120 and a power semiconductor die 130. The baseplate 120 comprises a first side 121, an opposite second side 122 and an edge 123 connecting the first and second sides 121, 122.

The power semiconductor module 110 may be configured to operate with a high electrical voltage and/or a high current. The power semiconductor module 110 may comprise any suitable circuitry, for example a converter circuit, an inverter circuit, a half-bridge circuit, etc.

The power semiconductor module 110 may comprise an encapsulant encapsulating the power semiconductor die 130 (not shown in FIG. 1). The encapsulant may for example comprise a molded body and/or a plastic frame. Furthermore, the power semiconductor module 110 may comprise external contacts which are exposed from the encapsulant. The external contacts may be configured as power contacts, control contacts, sensing contacts, etc.

The baseplate 120 may comprise or consist of any suitable material, in particular a metal or metal alloy. The baseplate 120 may for example comprise or consist of Al or Cu. The baseplate 120 may for example comprise a plating, in particular a Ni plating.

The baseplate 120 may have any suitable shape and any suitable dimensions. The baseplate 120 may for example have an essentially rectangular or quadratic shape as viewed from above the first side 121. The baseplate 120 may for example have a length and/or width in the range of about 3 cm to about 30 cm. The length and/or width may for example be about 6 cm, about 10 cm, about 14 cm, about 18 cm, about 22 cm, or about 26 cm. In the case of a rectangular shape, the width may for example be about 40% or about 60% or about 80% of the length of the baseplate 120.

Furthermore, the baseplate 120 may have any suitable thickness measured between the first and second sides 121, 122. The thickness of the baseplate 120 may for example be in the range of 2 mm to 20 mm, for example about 4 mm, about 8 mm, about 12 mm, or about 16 mm.

The power semiconductor die 130 is arranged at the first side 121 of the baseplate 120. According to an example, the power semiconductor module 110 comprises at least two power semiconductor dies 130. The at least two power semiconductor dies 130 may all be arranged at the first side 121 of the baseplate 120. The at least two power semiconductor dies 130 may be electrically coupled to each other in order to provide a suitable electrical circuit.

According to an example, the power semiconductor module 110 further comprises at least one power electronic substrate arranged between the power semiconductor die 130 and the baseplate 120. The power electronic substrate may comprise at least an electrically isolating layer. The power electronic substrate may further comprise a first and a second electrically conductive layer, wherein the first and second electrically conductive layers are arranged on opposite sides of the electrically isolating layer. The power electronic substrate may for example be a substrate of the type DCB (direct copper bonded), DAB (direct aluminum bonded), AMB (active metal brazed), etc.

In the case that the power semiconductor module 110 comprises more than one power electronic substrate, these power electronic substrates may all be arranged laterally next to each other on the first side 121 of the baseplate 120.

The power semiconductor die 130 may be arranged on the power electronic substrate. Soldering, sintering and/or gluing may be used to attach the power semiconductor die 130 to the power electronic substrate. Furthermore, the power semiconductor die 130 may be electrically coupled to the power electronic substrate (in particular, a power electrode on the lower side of the power semiconductor die 130 may be electrically coupled to the power electronic substrate).

The cooler 140 comprises an opening 141. The opening 141 may be arranged at an upper side of the cooler 140. The opening 141 may essentially have the same shape as the baseplate 120. The opening 141 may essentially have the same dimensions as the baseplate 120. Furthermore, a thickness of a wall of the cooler 140 may be similar or identical to the thickness of the baseplate 120. It is however also possible that the wall of the cooler 140 has a different thickness.

The cooler 140 may comprise or consist of a metal or metal alloy. The cooler 140 may for example comprise or consist of Al or Fe. The baseplate 120 and the cooler 140 may comprise or consist of the same metal or metal alloy or the baseplate 120 and the cooler 140 may comprise or consist of different metals or metal alloys. It is also possible that at least a part of the cooler 140 comprises or consists of a different material, e.g. a plastic. However, in this case the part of the cooler 140 which comprises the opening 141 (i.e. the part of the cooler 140 around the opening 141) may still consist of a metal or metal alloy. According to an example, a coefficient of thermal expansion of the material of the baseplate 120 is different from a coefficient of thermal expansion of the material of the cooler 140.

When the power semiconductor module 110 and the cooler 140 are assembled as shown in FIG. 1B, the edge 123 of the baseplate 120 may be in direct contact with an edge 142 of the opening 141. This means that a fluid channel 143 provided by the cooler 140 is sealed at the opening 141 by the baseplate 120. The second side 122 of the baseplate 120 forms a wall of the fluid channel 143. The fluid channel 143 may be configured to operate with any suitable cooling fluid, for example water or air.

The edge 123 of the baseplate 120 and the edge 142 of the opening 141 may essentially be arranged parallel to each other. The first side 121 of the baseplate 120 and an upper side of the cooler 140 may essentially be coplanar, as shown in FIG. 1B. This, however, does not necessarily have to be the case. It is also possible that the second side 122 of the baseplate 120 is coplanar with an inner side of the cooler 140. This as well does not necessarily have to be the case.

The baseplate 120 and the cooler 140 may be joined by a frictional connection between the edge 123 of the baseplate 120 and the edge 142 of the opening 141. In particular, an interface between the baseplate 120 and the cooler 140 at the opening 141 is free of any welded joint. The fluid channel may be sealed by the frictional connection at the opening 141 and no welded joint or solder joint may be necessary to provide sealing.

Such a frictional connection may be fabricated using a heat shrinking process or a thermal expansion process. In these processes, a change in temperature is used to either expand or shrink one of the join partners. Any suitable temperature difference may be applied, as long as the temperatures are not harmful for the components of the power electronic system 100. For example, a temperature difference of about 30° C. or more, or 40° C. or more, or 60° C. or more, or 80° C. or more, or 100° C. or more may be used for the heat shrinking or thermal expansion process.

The fact that the baseplate 120 and the cooler 140 are joined by a frictional connection also means that these two components are joined in a reversible manner. Heating up the cooler and/or cooling down the baseplate to a certain minimum relative temperature difference will release the joint. The minimum relative temperature difference may for example be about 30° C. or more, or 40° C. or more, or 60° C. or more, or 80° C. or more, or 100° C. or more.

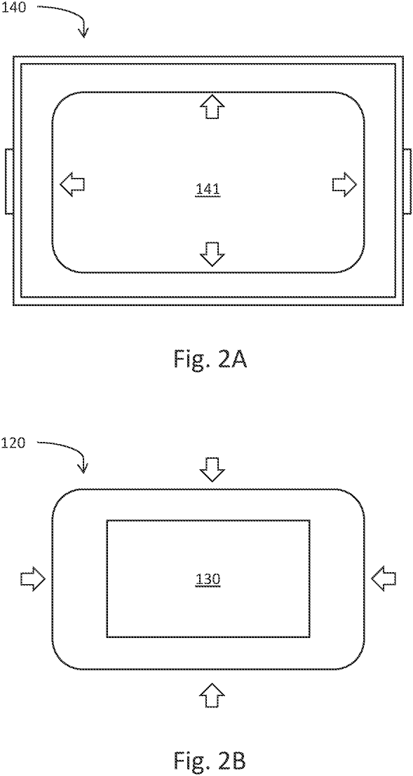

In the case of a heat shrinking process, the cooler 140 is heated up which causes the opening 141 to expand, as schematically shown in FIG. 2A. The baseplate 120 is inserted into the expanded opening 141 and the cooler 140 may then cool down to room temperature. This causes the opening 141 to shrink back and the frictional connection between the edges 123 and 142 is formed.

According to an example, a hot plate, an oven, a Bunsen burner, inductive heating, etc. may be used to heat up the cooler 140.

In the case of a heat expansion process, the baseplate 120 is cooled down which causes the baseplate 120 to shrink, as schematically shown in FIG. 2B. The shrunken baseplate 120 is inserted into the opening 141. When the baseplate 120 warms up again, the frictional connection is formed.

According to an example, a freezer, a cold bath, liquid nitrogen, etc. may be used to cool down the baseplate 120.

Joining the baseplate 120 and the cooler 140 using a frictional connection as described above instead of using e.g. screws or a welded joint may have several advantages. For example, the joining process may be less error-prone; the seal may be tighter; a smaller baseplate 120 may be used as explained further below; unlike with welding, no splinters are created by the joining process (in particular friction stir welding may create splinters which may contaminate components of the power electronic system 100); etc.

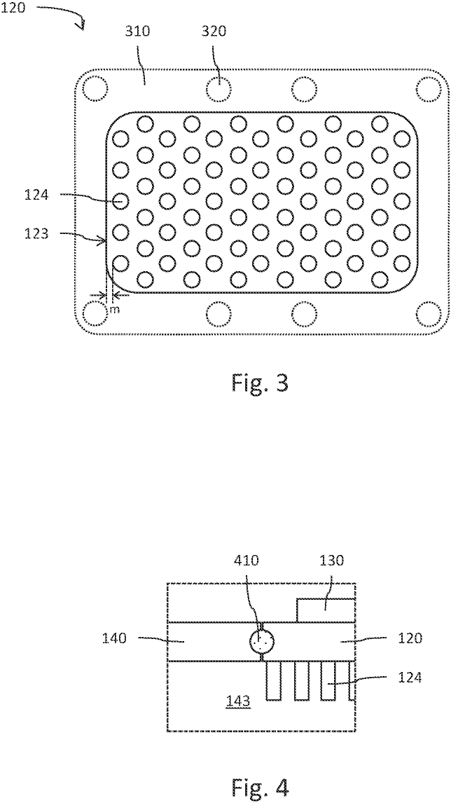

FIG. 3 shows a plan view of the second side 122 of the baseplate 120 according to a specific example. In particular, in the example shown in FIG. 3, the second side 122 comprises a plurality of cooling structures 124. The cooling structures 124 may be configured to extend into the fluid channel 143 and to be in direct contact with a cooling fluid within the fluid channel 143. The cooling structures 124 may for example comprise or consist of pins and/or ribbons. The cooling structures 124 may be contiguous with the rest of the baseplate 120 or the cooling structures 124 may be joined to the baseplate 120, for example by soldering or welding.

As shown in FIG. 3, the baseplate 120 is essentially free of any margin between the cooling structures 124 and the edge 123. “Essentially free of any margin” may mean that a margin m between the plurality of cooling structures 124 and the edge 123 of the baseplate 120 is 8 mm or less, or 5 mm or less, or 3 mm or less, or 1 mm or less.

The baseplate 120 is joined to the cooler 140 by the frictional connection generated by a heat shrinking process or a heat expansion process, as described above. For this reason, it may not be necessary to provide a comparatively large margin comprising fastening structures around the plurality of cooling structures 124. In FIG. 3, such a comparatively large margin 310 with fastening structures 320 (e.g. holes for screws) is indicated by dashed lines. By joining the baseplate 120 and the cooler 140 with a frictional connection, the surface area of the large margin 310 can be saved, significantly reducing the required size of the baseplate 120. For example, about 30% or more, or 40% or more of surface area of the baseplate 120 may be saved in this manner. Furthermore, because the baseplate 120 is joined to the cooler 140 via a frictional connection, it is not necessary to place screws into the fastening structures 320, saving process steps. Such savings may significantly reduce the costs of the power electronic system 100.

FIG. 4 shows a sectional view of a detail of the power electronic system 100, according to a specific example. In particular, FIG. 4 shows the interface between the baseplate 120 and the cooler 140.

In the example of FIG. 4, a polymer seal 410 is arranged between the edge 123 of the baseplate 120 and the edge 142 of the opening 141. The polymer seal 410 may for example comprise a seal ring. The edge 123 of the baseplate 120 and/or the edge 142 of the opening 141 may comprise a groove for accommodating the polymer seal 410.

According to an example, the edges 123, 142 do not touch and only the polymer seal 410 connects the edge 123 of the baseplate 120 to the edge 142 of the opening 141. According to another example, the edges 123, 142 above and/or below the polymer seal 410 actually touch.

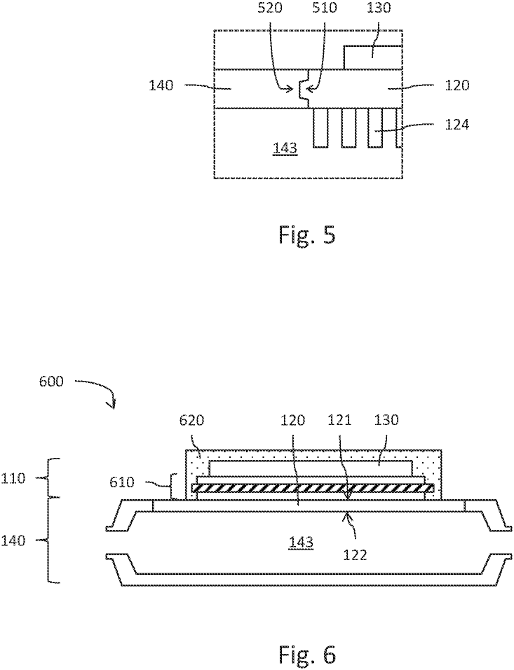

FIG. 5 shows a similar sectional view of a detail of the power electronic system 100 as FIG. 4, according to a further specific example.

In the example shown in FIG. 5, the edge 123 of the baseplate 120 comprises a ridge 510. The edge 142 of the opening 141 may comprise a corresponding notch 520, configured to receive the ridge 510. According to another example, the edge 142 of the opening 141 comprises the ridge 510 and the edge 123 of the baseplate 120 comprises the notch.

According to an example, the power electronic system 100 comprises both the polymer seal 410 and the ridge-notch structure 510, 520. The polymer seal 410 may for example be arranged within the notch 520 or above or below the notch 520.

FIG. 6 shows a further power electronic system 600 which may be similar or identical to the power electronic system 100, except for the differences described in the following.

In particular, the power electronic system 600 comprises a power electronic substrate 610 arranged between the power semiconductor die 130 and the baseplate 120. The power electronic substrate 610 comprises at least an electrically isolating layer. The power electronic substrate 610 may for example be a substrate of the type DCB, DAB, AMB, etc.

The power electronic substrate 610 may be part of the power semiconductor module 110. The power electronic substrate 610 may for example be attached to the baseplate 120 by one or more of soldering, welding, gluing, screwing and clamping.

According to an example, the power electronic system 600 comprises a plurality of power electronic substrates 610. The power electronic substrates 610 may be arranged laterally next to each other on a single baseplate 120 or on more than one baseplates 120.

The power electronic system 600 may comprise an encapsulant 620 encapsulating the power semiconductor die 130. The encapsulant 620 may for example comprise a molded body and/or a plastic frame. The encapsulant 620 may be joined to the baseplate 120 and/or to the power electronic substrate 610.

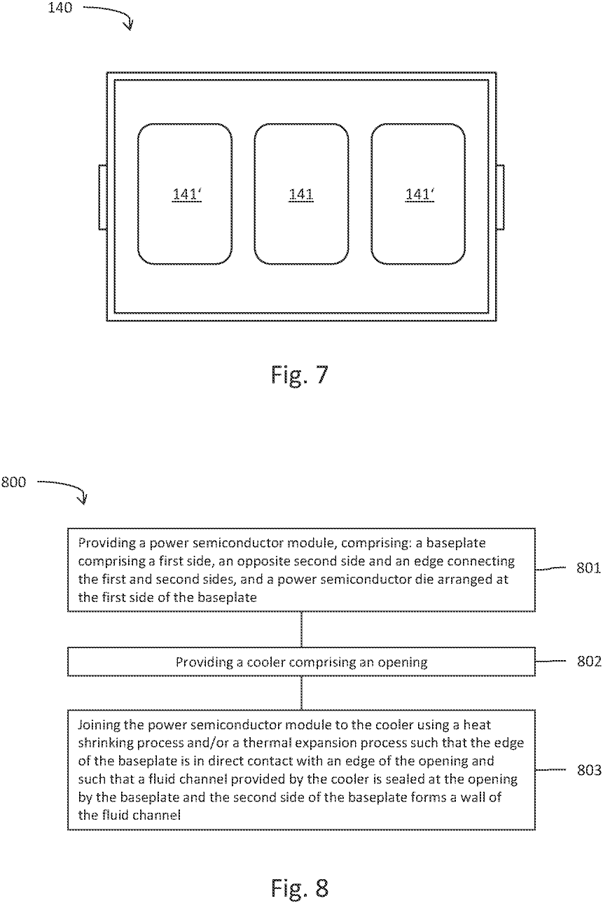

FIG. 7 shows a plan view of the cooler 140 according to a specific example. In particular, in this example the cooler 140 comprises not only the opening 141 but at least one further opening 141′. The cooler 140 may for example comprise two further openings 141′. The opening 141 and the at least one further opening 141′ may be arranged laterally next to each other on the same side of the cooler 140.

The further openings 141′ are configured to accept further baseplates 120 and to form a frictional connection with the respective further baseplate 120. In other words, in the example shown in FIG. 7, the cooler 140 is configured to be joined to more than one power semiconductor module 110. The more than one power semiconductor modules 110 may be identical modules or the more than one power semiconductor modules 110 may differ.

When a further baseplate 120 is arranged within a further opening 141′, an edge of the further baseplate 120 is in direct contact with an edge of the further opening 141′. Furthermore, the fluid channel 143 provided by the cooler 140 is sealed at the further opening 141′ by the further baseplate 120 and a second side of the further baseplate 120 forms a wall of the fluid channel 143.

FIG. 8 is a flow chart of an exemplary method 800 for fabricating a power electronic system. The method 800 may for example be used to fabricate the power electronic systems 100 and 600.

Method 800 comprises at 801 a process of providing a power semiconductor module, comprising: a baseplate comprising a first side, an opposite second side and an edge connecting the first and second sides, and a power semiconductor die arranged at the first side of the baseplate. Method 800 comprises at 802 a process of providing a cooler comprising an opening, and at 803 a process of joining the power semiconductor module to the cooler using a heat shrinking process and/or a thermal expansion process such that the edge of the baseplate is in direct contact with an edge of the opening and such that a fluid channel provided by the cooler is sealed at the opening by the baseplate and the second side of the baseplate forms a wall of the fluid channel.

In the following, the power electronic system and the method for fabricating a power electronic system are further explained using specific examples.

Example 1 is a power electronic system, comprising: a power semiconductor module, comprising: a baseplate comprising a first side, an opposite second side and an edge connecting the first and second sides and a power semiconductor die arranged at the first side of the baseplate; and a cooler comprising an opening, wherein the edge of the baseplate is in direct contact with an edge of the opening such that a fluid channel provided by the cooler is sealed at the opening by the baseplate and the second side of the baseplate forms a wall of the fluid channel, wherein an interface between the baseplate and the cooler at the opening is free of any welded joint.

Example 2 is the power electronic system of example 1, wherein the second side of the baseplate comprises a plurality of cooling structures extending into the fluid channel, and in particular wherein a margin between the plurality of cooling structures and the edge of the baseplate is 5 mm or less.

Example 3 is the power electronic system of example 1 or 2, further comprising: a polymer seal arranged between the edge of the baseplate and the edge of the opening.

Example 4 is the power electronic system of one of the preceding examples, wherein the edge of the baseplate and/or the edge of the opening comprises a ridge.

Example 5 is the power electronic system of one of the preceding examples, further comprising: a power electronic substrate arranged between the power semiconductor die and the baseplate, the power electronic substrate comprising at least an electrically isolating layer.

Example 6 is the power electronic system of one of the preceding examples, further comprising: a further power semiconductor module comprising a further baseplate, wherein the cooler comprises a further opening, wherein an edge of the further baseplate is in direct contact with an edge of the further opening such that the fluid channel provided by the cooler is sealed at the further opening by the further baseplate and a second side of the further baseplate forms a wall of the fluid channel.

Example 7 is the power electronic system of one of the preceding examples, wherein the baseplate comprises or consists of Cu and the cooler comprises or consists of Al.

Example 8 is the power electronic system of one of the preceding examples, wherein the power semiconductor module is held in place solely by a frictional connection between the edge of the baseplate and the edge of the opening.

Example 9 is a power electronic system, comprising: a power semiconductor module, comprising: a baseplate comprising a first side, an opposite second side and an edge connecting the first and second sides and a power semiconductor die arranged at the first side of the baseplate; and a cooler comprising an opening, wherein the edge of the baseplate is in direct contact with an edge of the opening such that a fluid channel provided by the cooler is sealed at the opening by the baseplate and the second side of the baseplate forms a wall of the fluid channel, wherein the power semiconductor module and the cooler are joined in a reversible manner wherein heating the cooler and/or cooling down the baseplate to a relative temperature difference of 60° C. or more will release the joint.

Example 10 is the power electronic system of example 9, wherein a coefficient of thermal expansion of the material of the baseplate is different from a coefficient of thermal expansion of the cooler.

Example 11 is a power electronic system, comprising: a power semiconductor module, comprising: a baseplate comprising a first side, an opposite second side and an edge connecting the first and second sides and a power semiconductor die arranged at the first side of the baseplate; and a cooler comprising an opening, wherein the edge of the baseplate is in direct contact with an edge of the opening such that a fluid channel provided by the cooler is sealed at the opening by the baseplate and the second side of the baseplate forms a wall of the fluid channel, wherein a joint between the baseplate and the cooler is fabricated by a heat shrinking process or a thermal expansion process.

Example 12 is the power electronic system of example 11, wherein an interface between the baseplate and the cooler at the opening is free of any welded joint.

Example 13 is a method for fabricating a power electronic system, the method comprising: providing a power semiconductor module, comprising: a baseplate comprising a first side, an opposite second side and an edge connecting the first and second sides and a power semiconductor die arranged at the first side of the baseplate, providing a cooler comprising an opening, and joining the power semiconductor module to the cooler using a heat shrinking process and/or a thermal expansion process such that the edge of the baseplate is in direct contact with an edge of the opening and such that a fluid channel provided by the cooler is sealed at the opening by the baseplate and the second side of the baseplate forms a wall of the fluid channel.

Example 14 is the method of example 13, wherein the heat shrinking process and/or the thermal expansion process comprises providing a temperature difference between the baseplate and the cooler of 60° C. or more.

Example 15 is the method of example 13 or 14, wherein a heat shrinking process is used and wherein the heat shrinking process comprises heating the cooler in an oven.

Example 16 is the method of one of examples 13 to 15, further comprising: providing a further power semiconductor module comprising a further baseplate, wherein the cooler comprises a further opening, wherein an edge of the further baseplate is in direct contact with an edge of the further opening such that the fluid channel provided by the cooler is sealed at the further opening by the further baseplate and a second side of the further baseplate forms a wall of the fluid channel, and wherein the further baseplate and the cooler are joined by the heat shrinking process or the thermal expansion process.

Example 17 is an apparatus comprising means for performing the method according to anyone of the examples 13 to 16.

While the disclosure has been illustrated and described with respect to one or more implementations, alterations and/or modifications may be made to the illustrated examples without departing from the spirit and scope of the appended claims. In particular regard to the various functions performed by the above described components or structures (assemblies, devices, circuits, systems, etc.), the terms (including a reference to a “means”) used to describe such components are intended to correspond, unless otherwise indicated, to any component or structure which performs the specified function of the described component (e.g., that is functionally equivalent), even though not structurally equivalent to the disclosed structure which performs the function in the herein illustrated exemplary implementations of the disclosure.

What is claimed is:

1. A power electronic system, comprising:
a power semiconductor module, comprising:
a baseplate comprising a first side, an opposite second side, and an edge connecting the first and second sides; and
a power semiconductor die arranged at the first side of the baseplate; and
a cooler comprising an opening,
wherein the edge of the baseplate is in direct contact with an edge of the opening such that a fluid channel provided by the cooler is sealed at the opening by the baseplate and the second side of the baseplate forms a wall of the fluid channel,
wherein a joint between the baseplate and the cooler is fabricated by a heat shrinking process or a thermal expansion process.

2. The power electronic system of claim 1, wherein the second side of the baseplate comprises a plurality of cooling structures extending into the fluid channel.

3. The power electronic system of claim 2, wherein a margin between the plurality of cooling structures and the edge of the baseplate is 5 mm or less.

4. The power electronic system of claim 1, further comprising:
a polymer seal arranged between the edge of the baseplate and the edge of the opening.

5. The power electronic system of claim 1, wherein the edge of the baseplate and/or the edge of the opening comprises a ridge.

6. The power electronic system of claim 1, further comprising:
a power electronic substrate arranged between the power semiconductor die and the baseplate, the power electronic substrate comprising at least an electrically isolating layer.

7. The power electronic system of claim 1, further comprising:
a further power semiconductor module comprising a further baseplate,
wherein the cooler comprises a further opening,
wherein an edge of the further baseplate is in direct contact with an edge of the further opening such that the fluid channel provided by the cooler is sealed at the further opening by the further baseplate and a second side of the further baseplate forms a wall of the fluid channel.

8. The power electronic system of claim 1, wherein the baseplate comprises or consists of Cu and the cooler comprises or consists of Al.

9. The power electronic system of claim 1, wherein the power semiconductor module is held in place solely by a frictional connection between the edge of the baseplate and the edge of the opening.

10. A method for fabricating a power electronic system, the method comprising:
providing a power semiconductor module, comprising:
a baseplate comprising a first side; an opposite second side; and an edge connecting the first and second sides; and
a power semiconductor die arranged at the first side of the baseplate,
providing a cooler comprising an opening; and
joining the power semiconductor module to the cooler using a heat shrinking process and/or a thermal expansion process such that the edge of the baseplate is in direct contact with an edge of the opening and such that a fluid channel provided by the cooler is sealed at the opening by the baseplate and the second side of the baseplate forms a wall of the fluid channel.

11. The method of claim 10, wherein the heat shrinking process and/or the thermal expansion process comprises providing a temperature difference between the baseplate and the cooler of 60° C. or more.

12. The method of claim 10, wherein the heat shrinking process is used to join the power semiconductor module to the cooler, and wherein the heat shrinking process comprises heating the cooler in an oven.

13. The method of claim 10, further comprising:
providing a further power semiconductor module comprising a further baseplate,
wherein the cooler comprises a further opening,
wherein an edge of the further baseplate is in direct contact with an edge of the further opening such that the fluid channel provided by the cooler is sealed at the further opening by the further baseplate and a second side of the further baseplate forms a wall of the fluid channel, and
wherein the further baseplate and the cooler are joined by the heat shrinking process or the thermal expansion process.
